(19) United States
(12) Patent Application Publication
(10) Pub. No.: US 2007/0246708 A1
(43) Pub. Date: Oct. 25, 2007

(54) SEMICONDUCTOR DEVICE

(75) Inventors: Kenichi Mori, Tokyo (JP); Shinsuke Sakashita, Tokyo (JP); Kazuki Tanaka, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/736,959

(22) Filed: Apr. 18, 2007

(30) Foreign Application Priority Data
Apr. 19, 2006 (JP) 2006-115693

(51) Int. Cl. H01L 29/04

(52) U.S. Cl. 257/59

(57) ABSTRACT

A semiconductor device comprising a high-dielectric film in a part of a gate insulation film is provided by a more simplified method. In a semiconductor device having a first region and a second region, a first gate electrode, a second gate electrode and a high-dielectric gate insulation film are formed in the first region (core part). The first gate electrode and the second gate electrode have different composition ratios. The first gate electrode and the second gate electrode are formed on the high-dielectric gate insulation film. Furthermore, a third gate electrode and a fourth gate electrode and a SiON film or SiO₂ film are formed in the second region (I/O part). Impurity elements doped in the third gate electrode and the fourth gate electrode are different in kind and/or concentration. In addition, the third gate electrode and the fourth gate electrode are formed on the SiON film or SiO₂ film.

### BACKGROUND OF THE INVENTION

1. Field of the Invention

The present invention relates to a semiconductor device and more particularly, to a semiconductor device having a plurality of gate electrode structure.

2. Description of the Background Art

According to a present general CMOS device, a plurality of operation voltages are separately used in a semiconductor device (that is, the operation voltages are different in the semiconductor device). Thus, the differentiation in the operation voltage is implemented by forming several kinds of gate electrode structures in the semiconductor device (that is, a plurality of transistors having different threshold voltages are formed in one semiconductor device).

For example, several kinds of gate structures are formed in one semiconductor device by varying a gate insulation film thickness or varying a channel dope (for example, Electronic Material Series, Physics of VLSI device”, by Seigo Kishino, Mitsumasa Koyanagi, published by Maruzen Co. Ltd, pp 115-121).

In addition, according to a mass-produced CMOS device, a silicon oxide film or a silicon oxynitride film is widely used as a gate insulation film. In addition, p type or n type polysilicon is widely used as a gate electrode.

Meanwhile, as the device is further miniaturized, a transistor containing a gate electrode and the like also needs to be miniaturized. As the transistor is miniaturized, the gate insulation film is also miniaturized. However, the miniaturization of the transistor in a predetermined region by thinning the film thickness of the gate insulation film physically approaches its limit.

Thus, a structure using a high-dielectric film (a high-k film having a dielectric constant higher than that of a SiON film) in the gate insulation film has been increasingly studied. Furthermore, it is necessary to use the plurality of threshold voltages separately in one semiconductor device because a plurality of gate electrode structures comprising a gate electrode structure having a gate insulation film comprising the high-dielectric film are formed. Thus, it is desirable that the semiconductor device having the above structure can be formed by more simplified steps.

### SUMMARY OF THE INVENTION

It is an object of the present invention to provide a semiconductor device in which a plurality of gate electrode structures including a gate electrode structure having a gate insulation film comprising a high-dielectric film are provided in order to separately use a plurality of threshold voltages in one semiconductor device, and the above constitution can be formed by more simplified steps.

According to the present invention, a semiconductor device comprises a first region and a second region. In the first region, a first gate electrode, a second gate electrode and a high-dielectric gate insulation film are formed. The first gate electrode comprises a first material composed of a predetermined metal element and another element at a first ratio. The second gate electrode comprises a second material composed of the predetermined metal element and the other element at a second ratio. The high-dielectric gate insulation film is formed between the first gate electrode and a semiconductor substrate, and between the second gate electrode and the semiconductor substrate. Furthermore, the high-dielectric gate insulation film is in contact with the first gate electrode or the second gate electrode and has a dielectric constant higher than that of SiON. In addition, in the second region, a third gate electrode, a fourth gate electrode and a gate insulation film are formed. The third gate electrode contains a first impurity element in a first concentration. The fourth gate electrode contains a second impurity element in the first concentration, or contains the first impurity element in a second concentration, or contains the second impurity element in the second concentration. The gate insulation film is formed between the third gate electrode and the semiconductor substrate and between the fourth gate electrode and the semiconductor substrate. In addition, the gate insulation film is in contact with the third gate electrode or the fourth gate electrode and comprises SiON film or SiO₂ film.

For example, it is assumed that the high-dielectric gate insulation film is used in the region where the gate electrode structure is required to be miniaturized and the SiON film or SiO₂ film is used in the other region. In this constitution, when the present invention is applied, it is not necessary to deposit metal materials by the number of different threshold voltages of the transistor and the like. Therefore, the semiconductor device having the plurality of transistors operating at the different threshold voltages can be manufactured by more simplified steps.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing an experimental result in which an effective work function is varied when the phase structure (composition) of a metal silicide film formed on a high-dielectric film is varied;

FIG. 2 is a view showing an experimental result in which the effective work function is not varied even when the kind and concentration of an impurity element doped in the metal silicide film formed on the high-dielectric film;

FIG. 3 is a view showing an experimental result in which the effective work function is not varied even when the phase structure (composition) of a metal silicide film formed on the SiON film;

FIG. 4 is a view showing an experimental result in which the effective work function is varied when the kind and concentration of the impurity element doped in the metal silicide film formed on the SiON film;

FIG. 5 is a sectional view showing the essential constitution of a semiconductor device according to an embodiment 1;

FIG. 6 is a process sectional view to explain a manufacturing method of the semiconductor device according to the embodiment 1;

FIG. 7 is a process sectional view to explain the manufacturing method of the semiconductor device according to the embodiment 1;

FIG. 8 is a process sectional view to explain the manufacturing method of the semiconductor device according to the embodiment 1;

FIG. 9 is a process sectional view to explain the manufacturing method of the semiconductor device according to the embodiment 1;

FIG. 10 is a process sectional view to explain the manufacturing method of the semiconductor device according to the embodiment 1;

FIG. 11 is a process sectional view to explain the manufacturing method of the semiconductor device according to the embodiment 1;

FIG. 12 is a process sectional view to explain the manufacturing method of the semiconductor device according to the embodiment 1;

FIG. 13 is a process sectional view to explain the manufacturing method of the semiconductor device according to the embodiment 1;

FIG. 14 is a process sectional view to explain the manufacturing method of the semiconductor device according to the embodiment 1;

FIG. 15 is a process sectional view to explain the manufacturing method of the semiconductor device according to the embodiment 1;

FIG. 16 is a process sectional view to explain the manufacturing method of the semiconductor device according to the embodiment 1;

FIG. 17 is a process sectional view to explain the manufacturing method of the semiconductor device according to the embodiment 1;

FIG. 18 is a view showing experimental data in which a phase structure (composition) is varied by varying the film thickness ratio between a polysilicon film and a metal silicide film;

FIG. 19 is a view showing another experimental data in which the phase structure (composition) is varied by varying the film thickness ratio between the polysilicon film and the metal silicide film;

FIG. 20 is a view showing another experimental data in which the phase structure (composition) is varied by varying the film thickness ratio between the polysilicon film and the metal silicide film;

FIG. 21 is a process sectional view to explain a manufacturing method of the semiconductor device according to an embodiment 2;

FIG. 22 is a process sectional view to explain the manufacturing method of the semiconductor device according to the embodiment 2;

FIG. 23 is a sectional view showing the essential constitution of the semiconductor device according to the embodiment 2;

FIG. 24 is a sectional view showing the essential constitution of a semiconductor device according to an embodiment 3;

FIG. 25 is a process sectional view to explain a manufacturing method of the semiconductor device according to the embodiment 3;

FIG. 26 is a process sectional view to explain the manufacturing method of the semiconductor device according to the embodiment 3;

FIG. 27 is a process sectional view to explain the manufacturing method of the semiconductor device according to the embodiment 3; and

FIG. 28 is a process sectional view to explain the manufacturing method of the semiconductor device according to the embodiment 3.

### DESCRIPTION OF THE PREFERRED EMBODIMENTS

It is thought that as a high-dielectric film (a high-k film having a dielectric constant higher than that of a SiON film) that is employed as a gate insulation film, a Hf compound is a material that is most likely to be practically used, for example. Here, the Hf compound includes HfO₂, HfSiO, HfSiON or HfAlSiON.

However, when a high-dielectric film such as the Hf compound is employed as a gate insulation film and n type and p type polysilicon is employed as a gate electrode that is in contact with the gate insulation film, a phenomenon called Fermi Level Pinning occurs. Thus, this phenomenon makes the adjustment of the threshold voltage of the transistor difficult (for example, C. Hobbs et al., VLSI Symp. Tech. Dig., (2003) 9).

Thus, when the high-dielectric film such as the Hf compound is employed as the gate insulation film, it is desirable that an electrical conductive material (metal, alloy, metal compound and the like) is used as the gate electrode that is in contact with the gate insulation film (that is, a metal gate structure). As a result, the electrode can be prevented from being depleted as well as preventing the Fermi Level Pinning phenomenon.

However, for example, when a core part and an I/O part are compared in a semiconductor device, the gate electrode structure has to be more miniaturized at the core part. Therefore, in the region in which the structure has to be further miniaturized in one semiconductor device, a metal gate electrode structure is formed such that the high-dielectric film is employed as the gate insulation film and the electric conductive material is used as the gate electrode that is in contact with the gate insulation film. In addition, a SiON film or SiO₂ film is employed as the gate insulation film in the region in which miniaturization is not really needed in the semiconductor device, whereby the gate electrode structure is formed.

In addition, as described above, in a normal semiconductor device, the threshold voltage of the transistor is separately used.

Therefore, even in the semiconductor device having the above gate electrode structure, it is necessary to use the threshold voltage of the transistor separately.

Here, when the SiON film or the SiO₂ film is used as the gate insulation film, a difference in impurity element doped in the gate electrode that is in contact with the gate insulation film or a difference in concentration of the impurity element is to be used. Thus, in one semiconductor device, transistors having different threshold voltages can be formed.

Meanwhile, when the high-dielectric film is used as the gate insulation film, as a method for forming transistors having different threshold voltages in one semiconductor device, a difference in electric conductive material (metal material) constituting the gate electrode that is in contact with the gate insulation film is used. This is because when the kind of the gate insulation film (high-dielectric film) and the kind of the gate electrode (metal material) are determined, an effective work function is determined.

However, as described above, when the several kinds of the metal materials constituting the gate electrodes are separately used, the manufacturing steps of the semiconductor device becomes complicated. This is because it is necessary to separately use the different kinds of metal materials by the number of the different threshold voltages of the transistor, and processes such as deposition and etching are needed for each metal material.

Therefore, in view of simplification in the manufacturing steps, when the high-dielectric film is used as the gate insulation film, as a method for forming transistors having the different threshold voltages, another method is to be provided.

Here, the inventors focused on the following interesting measured result.

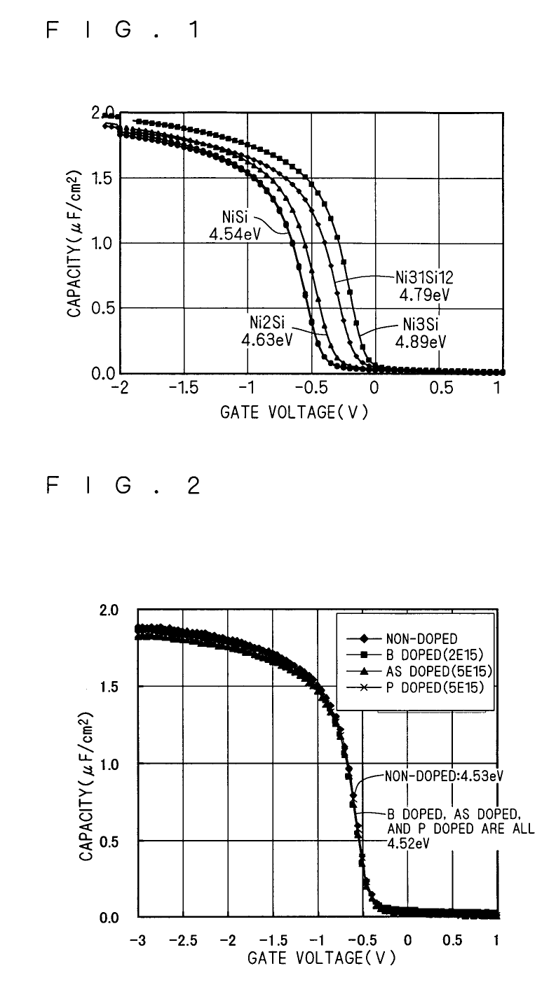

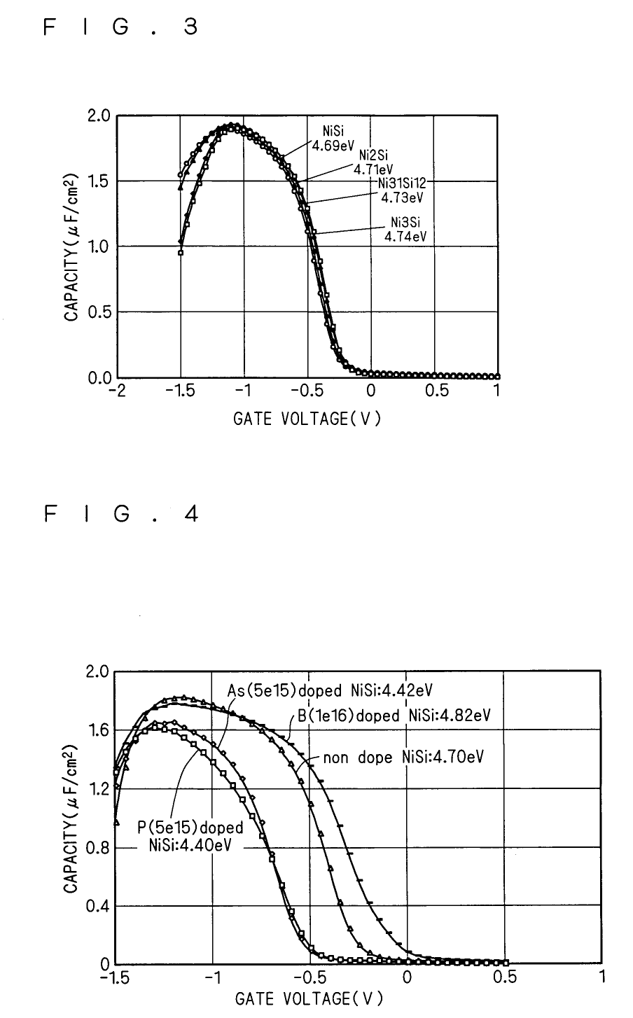

FIG. 1 is a graph of an experimental result showing the relation between the effective work function and the phase structure (composition) of a predetermined material constituting the gate electrode when the high-dielectric film is used as the gate insulation film. In addition, FIG. 2 is a graph of an experimental result showing the relation between the effective work function and the impurity element doped in the gate electrode when the high-dielectric film is used as the gate insulation film.

Here, in FIG. 1, the vertical axis indicates capacity (μF/cm²) and the horizontal axis indicates the gate voltage (V). In addition, the gate insulation film comprises HfSiON and the gate electrode comprises non-doped nickel silicide. In FIG. 2, the vertical axis indicates capacity (μF/cm²) and the horizontal axis indicates the gate voltage (V). In addition, the gate insulation film comprises HfSiON and the gate electrode comprises nickel silicide.

As can be seen from FIG. 1, when the phase structure (composition) of nickel silicide is different, the effective work function of the transistor varies (for example, the effective work function of NiSi is 4.54 eV, the effective work function of Ni₂Si is 4.63 eV, the effective work function of Ni₃₁Si₁₂ is 4.79 eV, and the effective work function of Ni₃Si is 4.89 eV).

In addition, when the condition (structure) other than the phase structure (composition) is the same, the threshold voltage of the transistor depends on the effective work function only. Therefore, as will be described below, when the condition (structure) other than the phase structure (composition) is the same, and the phase structure (composition) of the gate electrode formed on the high-dielectric gate insulation film is different as described above, the threshold voltages of the transistors differ.

Meanwhile, as can be seen from FIG. 2, even when the impurity element having a predetermined conductive type doped in the gate electrode is varied, the effective work function (that is, when the condition (structure) other than the phase structure (composition) is the same, the threshold voltage of the transistor) does not vary.

Here, FIG. 2 shows C—V curves in the case nothing is doped, the case B (boron) is doped in the concentration of 2E15, the case As (arsenic) is doped in the concentration of 5E15, and the case P (phosphorus) is doped in the concentration of 5E15. When the gate electrode is non-doped, the effective work function is 4.53 eV and when the impurity element is doped in the gate electrode, the effective work function is 4.52 eV.

As a result of the series of experiments including the above experimental result, the inventors found the following conclusion.

That is, when the high-dielectric film is employed as the gate insulation film, the transistors having several kinds of threshold voltages can be formed in one semiconductor device by varying the phase structure (composition) of the material (metal material) of the gate electrode that is in contact with the gate insulation film. Here, the transistor structure except that the phase structure is varied is the same.

More specifically, it is assumed that in the gate electrode structure having the high-dielectric gate insulation film having a dielectric constant higher than that of the SiON film, a first gate electrode that is in contact with the high-dielectric gate insulation film comprises a first material composed of a predetermined metal element and another element at a first ratio, and a second gate electrode that is in contact with the high-dielectric gate insulation film comprises a second material composed of the predetermined metal element and the other element at a second ratio (different from the first ratio). Thus, the phase structure (composition) of the gate electrode structure is different from each other as described above.

In this case, the transistor having the first gate electrode and the transistor having the second gate electrode have different threshold voltages. In addition, as described above, the condition (structure) other than the phase structure (composition) is the same.

Furthermore, the inventors also focused on the following interesting measured result.

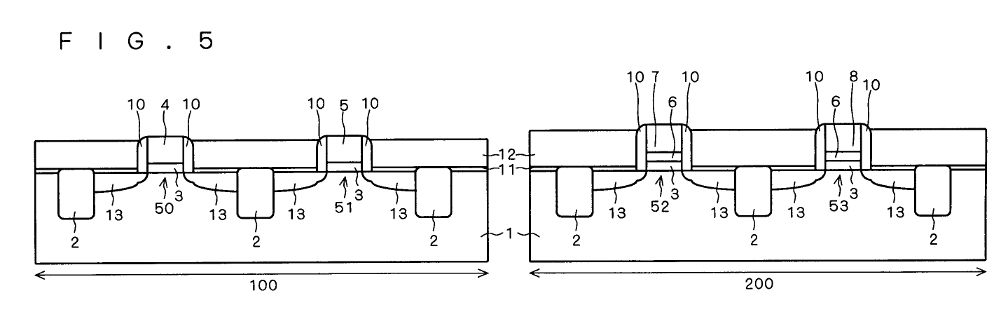

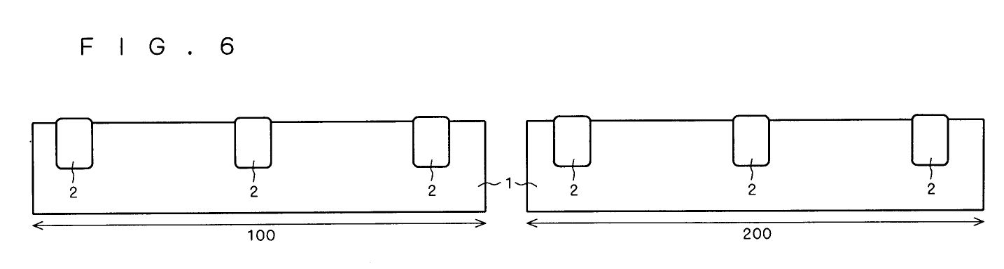

FIG. 3 is a graph of an experimental result showing the relation between an effective work function and a phase structure (composition) of the predetermined material constituting the gate electrode when the SiON film is employed as the gate insulation film that is in contact with the gate electrode. In addition, FIG. 4 is a graph of an experimental result showing the relation between the effective work function and the impurity element doped in the gate electrode when the SiON film is employed as the gate insulation film that is in contact with the gate electrode.

Here, in FIG. 3, the vertical axis indicates a capacity (μF/cm²) and the horizontal axis indicates a gate voltage (V). In addition, the gate insulation film is the SiON and the gate electrode is non-doped nickel silicide. Furthermore, in FIG. 4, the vertical axis indicates a capacity (μF/cm²) and the horizontal axis indicates a gate voltage (V). In addition, the gate insulation film is SiON and the gate electrode is nickel silicide.

As can be seen from FIG. 3, even when the phase structure (composition) of nickel silicide is varied, the effective work function hardly varies (for example, the effective work function of NiSi is 4.69 eV, the effective work function of Ni₂Si is 4.71 eV, the effective work function of Ni₃₁Si₁₂ is 4.73 eV, and the effective work function of Ni₃Si is 4.74 eV)

Meanwhile, as can be seen from FIG. 4, when the impurity element having a predetermined conductivity type doped in the gate electrode is varied, the effective work function is varied (for example, the effective work function of the gate electrode comprising NiSi in which P (concentration is 5e15) is doped is 4.40 eV, the effective work function of the gate electrode comprising NiSi in which As (concentration is 5e15) is doped is 4.42 eV, the effective work function of the gate electrode comprising non-doped NiSi is 4.70 eV, and the effective work function of the gate electrode comprising NiSi in which B (concentration is 1e16) is doped is 4.82 eV).

In addition, when the transistor structure other than the gate electrode is the same, as described above, the threshold voltage of the transistor only depends on the effective work function determined by the gate electrode material. In addition, the experimental result similar to the above has been provided when the SiO₂ film is used as the gate insulation film.

As the result of a series of experiments including the above experimental result, the inventors have also found the following conclusion.

That is, when the SiON film or the SiO₂ film is employed as the gate insulation film that is in contact with the gate electrode, even if the phase structure (composition) of the material (metal material) of the gate electrode is varied, the threshold voltage of the transistor is not varied. Meanwhile, the transistors having the several kinds of threshold voltages can be formed in one semiconductor device by varying the impurity element having a predetermined conductivity type to be doped in the gate electrode. Here, the structure of the component is the same as that of the other transistor.

More specifically, in the gate electrode structure in which the gate insulation film that is in contact with the gate electrode is the SiON film or SiO₂ film, it is assumed that a third gate electrode that is in contact with the gate insulation film contains a first impurity element in a first concentration, and a fourth gate electrode that is in contact with the gate insulation film contains a second impurity element in the first concentration, or contains the first impurity element in a second concentration different from the first concentration, or contains the second impurity element in the second concentration.

In this case, the transistor having the third gate electrode and the transistor having the fourth gate electrode are different in threshold voltage. Here, as described above, the structure of the component is the same as that of the other transistor.

Therefore, in the following embodiment, a semiconductor device comprising the following constitution will be described based on the conclusion from the above experimental result.

That is, in the region where the gate insulation film is required to be thinned (for example, EOT (Equivalent Oxide Thickness) is to be reduced (regarded as a first region), the high-dielectric film is employed as the gate insulation film. Thus, the phase structure (composition) of the gate electrode that is in contact with the high-dielectric gate insulation film is varied in the gate electrode structure formed in the first region. Thus, in the first region, the threshold voltage of the transistor is varied. In addition, even when the impurity ion having a predetermined conductivity type is doped in the gate electrode, in the gate electrode structure formed in the first region, the threshold voltage of the transistor is not varied. In addition, as described above, the transistor formed in the first region has the same structure of the component as that of the other transistor.

Furthermore, in the region where the gate insulation film is not really required to be thinned (for example, the EOT is not really to be reduced (regarded as a second region), the SiON film or the SiO₂ film is employed as the gate insulation film that is in contact with the gate electrode. Thus, in the gate electrode structure formed in the second region, the kind and/or concentration of the impurity element having a predetermined conductivity to be doped in the gate electrode is varied. Thus, in the second region, the threshold voltage of the transistor is varied. In addition, even when the phase structure (composition) of the metal material constituting the gate electrode is varied in the gate electrode structure formed in the second region, the threshold voltage of the transistor is not varied. Furthermore, as described above, other component constitution of the transistor formed in the second region has the same as component constitution of the other transistor.

Therefore, the semiconductor device according to the present invention has the following characteristics.

That is, the semiconductor device has the first region and the second region. Furthermore, in the gate electrode structure formed in the first region, the high-dielectric gate insulation film is formed and focusing on the gate electrode that is in contact with the high-dielectric gate insulation film, it has two or more kinds of phase structures (compositions). In addition, in the gate electrode structure formed in the second region, the gate insulation film that is in contact with the gate electrode is the SiON film or SiO₂ film, and focusing on the gate electrode, the kind and/or concentration of the doped impurity element is different.

Thus, when the semiconductor device having the above constitution is used, since the high-dielectric gate insulation film is provided, in order to form the transistors having the different threshold voltages, it is not necessary to deposit or etch the several kinds of metal materials (that is, it is not necessary to separately use the several kinds of metal materials).

Therefore, when the semiconductor device having the high-dielectric gate insulation film and several kinds of transistors having different threshold voltages is manufactured, its manufacturing steps can be simplified.

In addition, according to the semiconductor device in the present invention, the way the transistors having the different threshold voltages are formed is that only the phase structure (composition) of the gate electrode formed on the high-dielectric gate insulation film is to be varied in the first region (that is, only the constitution ratio is to be varied without varying the constitution material of the gate electrode). Furthermore, in the second region, only the kind and/or concentration of the impurity element having a predetermined conductivity type in the gate electrode formed on the gate insulation film comprising SiON film or SiO₂ film is to be varied.

The present invention will be described in detail with reference to the drawings showing the embodiments hereinafter.

### Embodiment 1

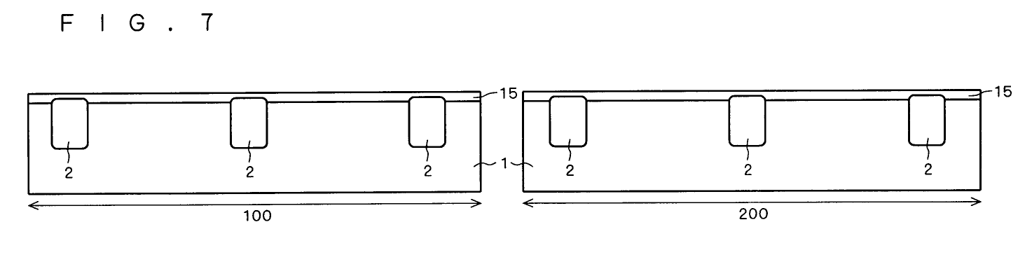

FIG. 5 is a sectional view showing an essential constitution of a semiconductor device according to this embodiment. As shown in FIG. 5, the semiconductor device according to this embodiment comprises a core part 100 and an I/O part 200. Here, the core part 100 is a region in which a gate insulation film is required to be thinned (EOT is required to be reduced, for example), which is regarded as a first region. The I/O part 200 is a region in which a gate insulation film is not really required to be thinned (EOT is not really required to be reduced, for example), which is regarded as a second region.

As shown in FIG. 5, a plurality of element isolation films 2 are provided to electrically isolate elements in the surface of a semiconductor substrate 1 such as a silicon substrate. In addition, a plurality of gate electrode structures are formed on the semiconductor substrate 1.

A first gate electrode structure 50 and a second gate electrode structure 51 are formed in the core part 100. In addition, a third gate electrode structure 52 and a fourth gate electrode structure 53 are formed in the I/O part 200.

Here, a transistor having the first gate electrode structure 50 and a transistor having the third gate electrode structure 52 are NMOS transistors. In addition, a transistor having the second gate electrode structure 51 and a transistor having the third gate electrode structure 53 are PMOS transistors.

Each of the first gate electrode structure 50 and the second gate electrode structure 51 comprises a gate insulation film having a high dielectric constant (that is, a gate insulation film having a dielectric constant higher than that of SiON which is referred to as the high-dielectric gate insulation film 3 hereinafter). Gate electrodes 4 and 5 are formed on the high-dielectric gate insulation film 3 so as to be in directly contact with each other.

That is, each of the gate electrode 4 constituting the first gate electrode structure 50 and the gate electrode 5 constituting the second gate electrode structure 51 comprises Ni (regarded as a metal element) and Si (regarded as another element). However, the gate electrodes 4 and 5 have different phase structures (compositions). That is, while the gate electrode 4 comprises NiSi (whose composition ratio is such that nickel:silicon=1:1), the gate electrode 5 comprises Ni₃Si (whose composition ratio is such that nickel:silicon=3:1).

Meanwhile, each of the third gate electrode structure 52 and the fourth gate electrode structure 53 comprises a gate insulation film in which a high-dielectric gate insulation film 3 and a SiON film (or a SiO₂ film, but the SiON film is employed in the following description) are stacked in this order. Gate electrodes 7 and 8 are formed on the SiON gate electrodes 6 so as to be directly in contact with each other.

That is, an impurity element having a predetermined conductivity type is doped in each of the gate electrode 7 constituting the third gate electrode structure 52 and the gate electrode 8 constituting the fourth gate electrode structure 53. However, the kinds and/or concentrations of the impurity elements in the gate electrodes 7 and 8 are different from each other.

Here, according to this embodiment, the gate electrodes 4, 5, 7 and 8 comprise metal silicide.

In addition, sidewall film 10 is formed on each side of the gate electrode structures 50 to 53. In addition, a silicide film 11 and an interlayer insulation film 12 are formed in this order on the semiconductor substrate 1 among the gate electrode structures 50 to 53 in a sectional view. In addition, an impurity diffusion region 13 is formed in the semiconductor substrate 1 on each side of the gate electrode structures 50 to 53 in a sectional view.

Next, a manufacturing method of the semiconductor device shown in FIG. 5 will be described in detail with reference to process sectional views.

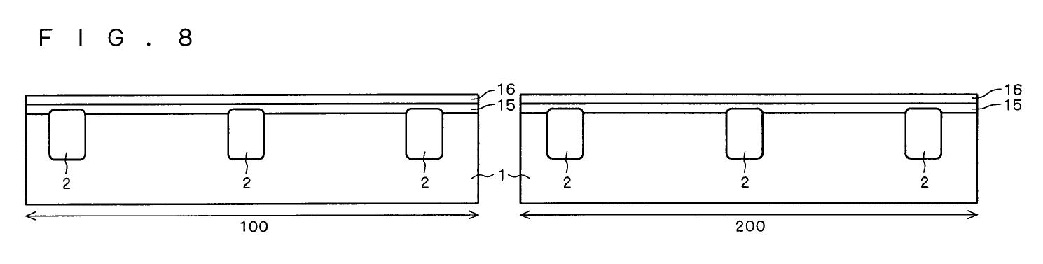

First, the semiconductor substrate 1 such as a silicon substrate having the core part (first region) 100 and the I/O part (second region) 200 is prepared. Then, as shown in FIG. 6, a well (not shown) and the element isolation film 2 are formed in the semiconductor substrate 1.

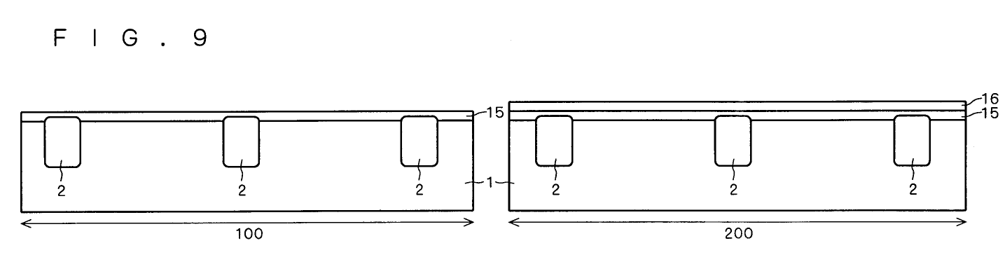

Then, as shown in FIG. 7, a hafnium silicon oxynitride (HfSiON) film 15 is formed on the semiconductor substrate 1. Here, the dielectric constant of the HfSiON film 15 is higher than that of silicon oxynitride (SiON) (that is, the HfSiON film 15 is a high-dielectric film). Furthermore, as shown in FIG. 8, a SiON film 16 is formed on the HfSiON film 15.

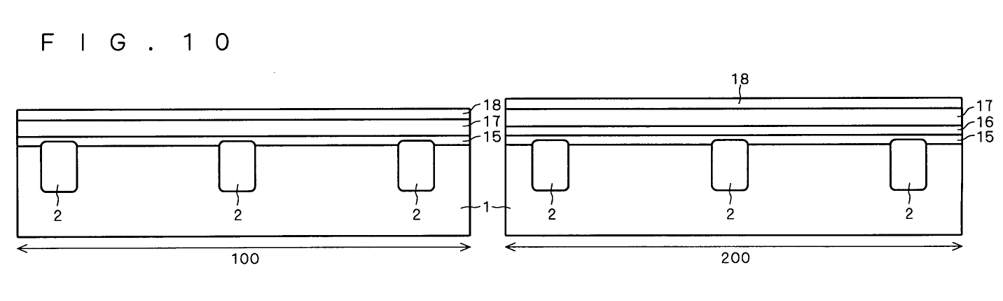

Then, the SiON film 16 is processed by photochemical engraving and etching. Thus, as shown in FIG. 9, the SiON film 16 in the core part 100 is removed. That is, the SiON film 16 exists in the I/O part 200 only.

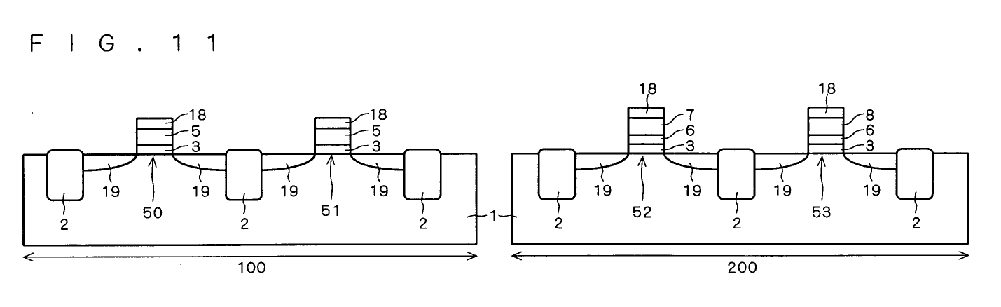

Then, a polysilicon film 17 and a silicon nitride (SiN) film 18 are formed in this order above the semiconductor substrate 1 shown in FIG. 9. Thus, as shown in FIG. 10, in the core part 100, the polysilicon film 17 and the SiN film 18 are formed in this order on the HfSiON film 15. In addition, as shown in FIG. 10, in the I/O part 200, the polysilicon film 17 and the SiN film 18 are formed on the SiON film 16 in this order. Here, the thickness of the polysilicon film 17 is about 120 nm.

Then, an impurity element having a predetermined conductivity type is doped in a predetermined region of the polysilicon film 17 in a desired concentration. Here, according to this embodiment, As (arsenic) or P (phosphorous) are doped in the polysilicon film 17 in which the gate electrode structure 50 and the gate electrode structure 52 are to be formed, and B (boron) is doped in the polysilicon film 17 in which the gate electrode structure 51 and the gate electrode structure 53 are to be formed.

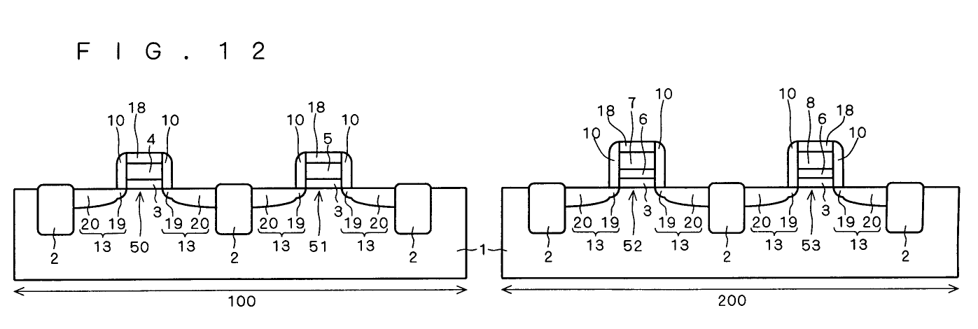

Furthermore, after the ion implantation, the HfSiON film 15, the SiON film 16, the polysilicon film 17 and the SiN film 18 are processed by photochemical engraving and etching. Thus, as shown in FIG. 11, the gate electrode structures 50 to 53 are formed. Here, each of the gate electrode structures 50 to 53 has the following structure at this point as will be described below.

That is, the gate electrode structure 50 comprises the high-dielectric gate insulation film 3 comprising the HfSiON film and the gate electrode 4 comprising the polysilicon film in which As or P is doped. In addition, the gate electrode structure 51 comprises the high-dielectric gate insulation film 3 comprising the HfSiON film and the gate electrode 5 comprising the polysilicon film in which B is doped.

Furthermore, the gate electrode structure 52 comprises the gate insulation film comprising the HfSiON film (high-dielectric gate insulation film 3) and the SiON gate insulation film 6 laminated in this order, and the gate electrode 7 comprising the polysilicon film in which As or P is doped. In addition, the gate electrode structure 53 comprises the gate insulation film comprising the HfSiON film (high-dielectric gate insulation film 3) and the SiON gate insulation film 6 laminated in this order, and the gate electrode 8 comprising the polysilicon film in which B is doped.

In addition, according to the gate electrode structures 50 to 53, the SiN films 18 are formed on the gate electrodes 4, 5, 7 and 8 (refer to FIG. 11).

According to the manufacturing steps again, an impurity element having a predetermined conductivity type is doped in the semiconductor substrate 1 in a desired concentration using the gate electrode structures 50 to 53 as masks before the sidewall film 10 that will be described below is formed. Thus, as shown in FIG. 11, a first extension region 19 is formed in the semiconductor substrate 1 at each side of the gate electrode structures 50 to 53.

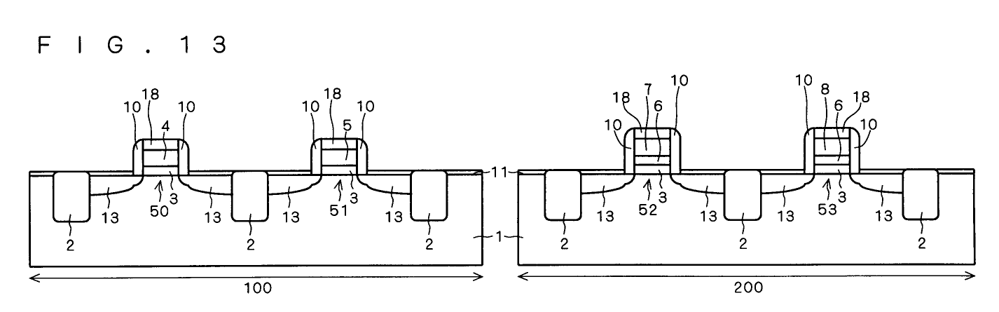

Then, a SiN film is formed on the semiconductor substrate 1 so as to cover the gate electrode structures 50 to 53. Then, the SiN film is processed by anisotropic etching. Thus, as shown in FIG. 12, the sidewall film 10 is formed on each side of the gate electrode structures 50 to 53.

Then, an impurity element having a predetermined conductivity type is doped in the semiconductor substrate 1 in a predetermined concentration using the gate electrode structures 50 to 53 having the sidewall film 10 on each side as masks. Thus, as shown in FIG. 12, a second extension region 20 is formed in the semiconductor substrate 1 on each side of the gate electrode structures 50 to 53. In addition, the impurity diffusion region (that can be regarded as a source and a drain regions) 13 is formed by the first extension region 19 and the second extension region 20. In addition, the impurity diffusion region 13 is activated by heat treatment.

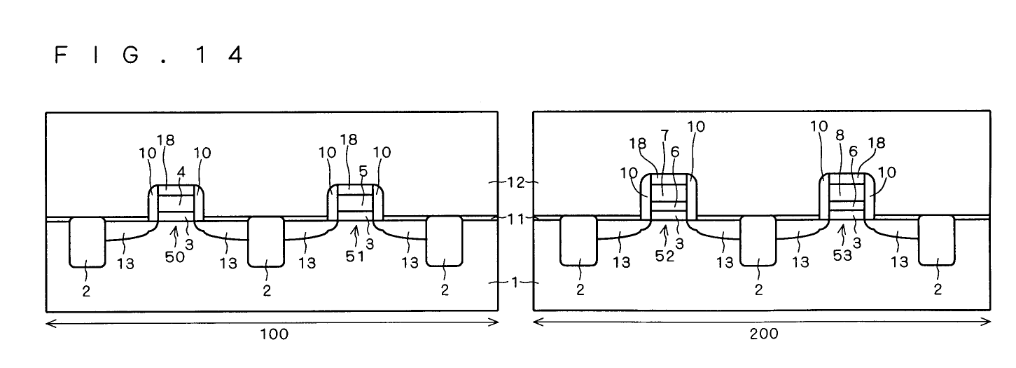

Then, the exposed upper surface of the semiconductor substrate 1 is silicided. Thus, as shown in FIG. 13, a silicide layer 11 such as Ni silicide is formed on the upper surface of the semiconductor substrate 1. More specifically, the silicide layer 11 is formed on the impurity diffusion region (that can be regarded as the source and drain regions) 13.

Through the above steps, the plurality of transistors are formed on the semiconductor substrate 1.

Next, steps for adjusting the threshold voltage of the transistor formed on the core part 100 will be described hereinafter.

First, the interlayer insulation film 12 is formed on the silicide layer 11 so as to cover the gate electrode structures 50 to 53 (refer to FIG. 14).

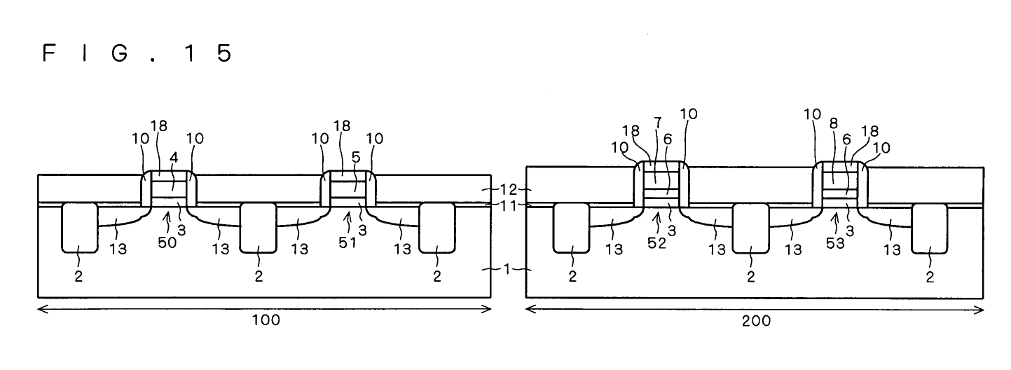

Then, the semiconductor device in the course of manufacturing shown in FIG. 14 is processed by CMP (Chemical Mechanical Polishing). Thus, the upper part of the interlayer film 12 is partially removed and the SiN film 18 formed at each upper part of the gate electrode structures 50 to 53 is exposed from the upper surface of the interlayer insulation film 12 as shown in FIG. 15.

Then, the SiN film 18 existing at the upper part of the gate electrode structure 51 (PMOS transistor) formed in the core part 100 is processed by photochemical engraving and etching. Thus, the SiN film 18 existing at the upper part of the gate electrode structure 51 is removed. Then, the gate electrode 5 constituting the gate electrode structure 51 (the gate electrode 5 comprises polysilicon at this point) is processed by etching. Thus, the thickness of the gate electrode 5 is reduced to about ⅔ (that is, the thickness of about 120 nm of the gate electrode 5 is reduced to about 40 nm).

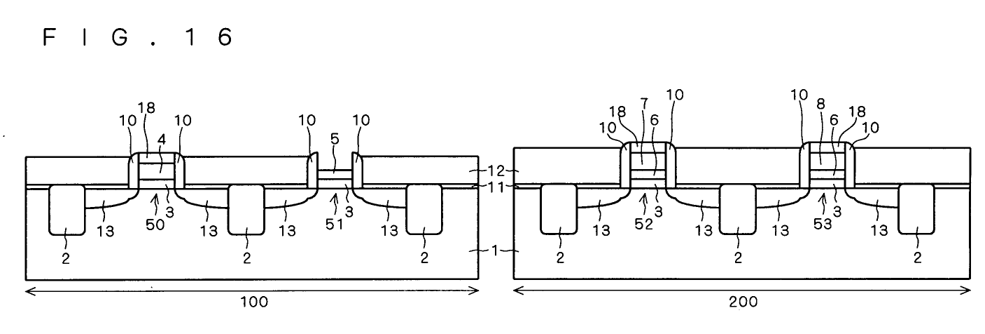

The semiconductor device manufactured up to this step is shown in FIG. 16.

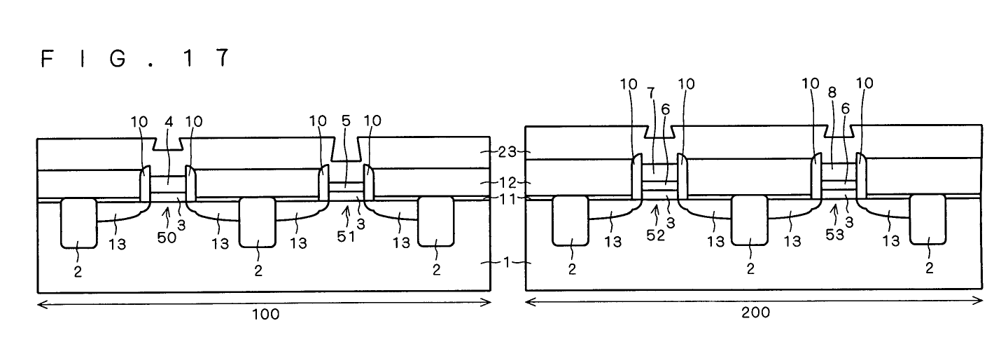

Then, the SiN films 18 existing on the other gate electrode structures 50, 52 and 53 are also removed in the same manner. Then, a Ni film 23 is formed on the interlayer insulation film 12 so as to fill each upper part of the gate electrode structures 50 to 53. In addition, the thickness of the Ni film 23 is about 150 nm. The semiconductor device manufactured up to this step is shown in FIG. 17.

Here, as shown in FIG. 17, each upper part of the gate electrode structures 50 to 53 is recessed. Therefore, as shown in the sectional view in FIG. 17, the Ni film 23 at each upper part of the gate electrode structures 50 to 53 is also recessed because of the above recession.

Then, the semiconductor device shown in FIG. 17 is processed by RTA (Rapid Thermal Anneal), whereby the gate electrodes 4, 5, 7 and 8 are silicided (that is, the gate electrodes 4, 5, 7 and 8 become metal silicide).

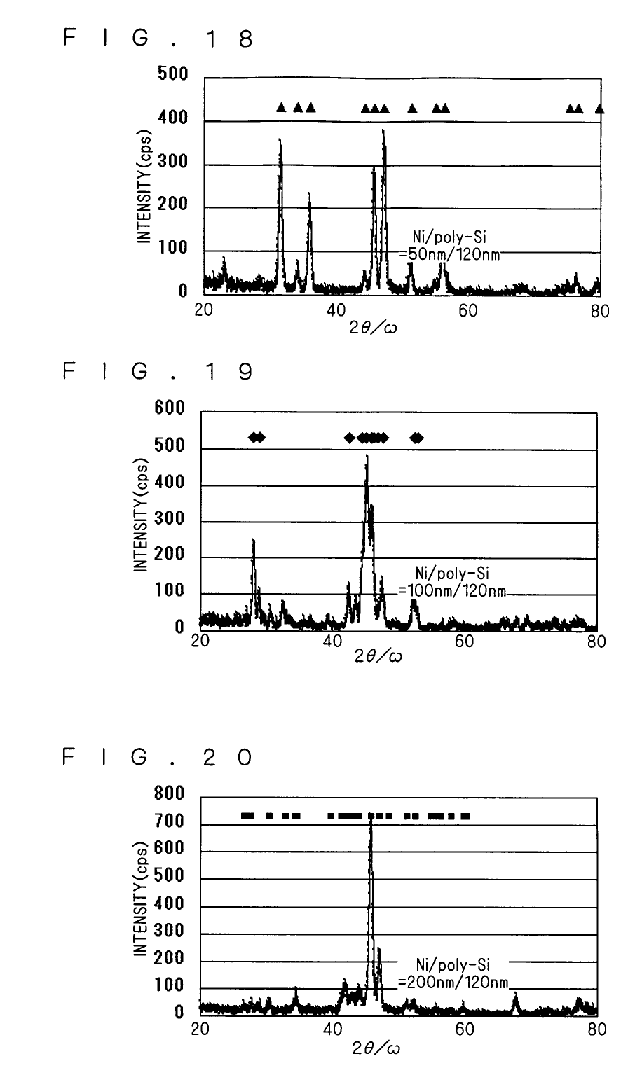

Here, when the film thickness ratio between the polysilicon (gate electrode) and the Ni film is varied, the phase structure (composition) of Ni silicide is varied. FIGS. 18, 19 and 20 show experimental results showing the relation between the film thickness and phase structure of Ni silicide (more specifically, evaluation results of the crystal structure of Ni silicide by X-ray diffraction method).

In FIGS. 18 to 20, the vertical axis indicates intensity (cps) and the horizontal axis indicates 20 (diffraction angle)/ω. In addition, the sample in FIGS. 18 to 20 is provided by forming a SiO₂ film on a silicon substrate by 100 nm, stacking polysilicon and Ni in this order on the SiO₂ film at the following ratio, and silicide it by RTA process. Here, all of the samples were processed by the RTA under the same heat treatment condition.

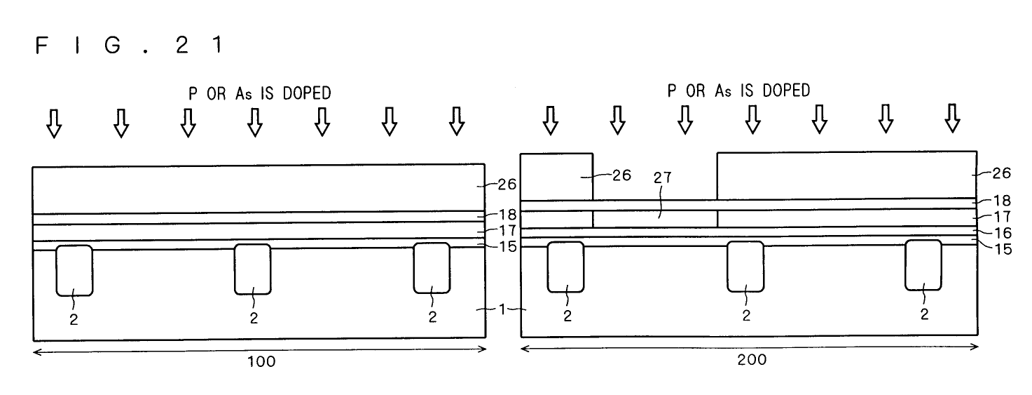

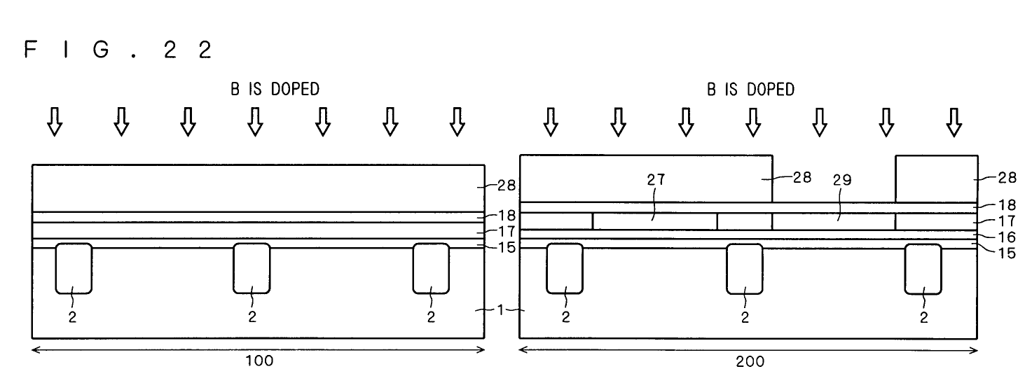

In addition, according to the sample shown in FIG. 18, polysilicon and Ni have been formed at a film thickness ratio such that Ni/polysilicon=50 nm/120 nm. According to the sample shown in FIG. 19, polysilicon and Ni have been formed at a film thickness ratio such that Ni/polysilicon=100 nm/120 nm. According to the sample shown in FIG. 20, polysilicon and Ni have been formed at a film thickness ratio such that Ni/polysilicon=200 nm/120 nm.

In addition, “black triangular marks” in FIGS. 18 to 20 indicate positions in which diffraction peak of NiSi will appear. In addition, “black rhombic marks” indicate positions in which diffraction peak of Ni₃Si₂ will appear. Furthermore, “black rectangular marks” indicate positions in which diffraction peak of Ni₃₁Si₁₂ will appear.

Referring to FIG. 18, the diffraction peak position of the X ray almost corresponds to the position of the “black triangular mark”. Thus, it can be determined that the sample shown in FIG. 18 (that is, the sample provided by forming polysilicon and Ni at the film thickness ratio such that Ni/polysilicon=50 nm/120 nm and siliciding it by RTA) is NiSi (that is, its composition ratio is such that Ni:Si=1:1).

Referring to FIG. 19, the diffraction peak position of the X ray almost corresponds to the position of the “black rhombic mark”. Thus, it can be determined that the sample shown in FIG. 19 (that is, the sample provided by forming polysilicon and Ni at the film thickness ratio such that Ni/polysilicon=100 nm/120 nm and siliciding it by RTA) is Ni₃Si₂ (that is, its composition ratio is such that Ni:Si=3:2).

Referring to FIG. 20, the diffraction peak position of the X ray almost corresponds to the position of the “black rectangular mark”. Thus, it can be determined that the sample shown in FIG. 20 (that is, the sample provided by forming polysilicon and Ni at the film thickness ratio such that Ni/polysilicon=200 nm/120 nm and siliciding it by RTA) is Ni₃₁Si₁₂ (that is, its composition ratio is such that Ni:Si=31:12).

As can be seen from the above experimental results, when the film thickness ratio between polysilicon and Ni (metal to be silicided) is varied, the phase structure (composition) of Ni silicide (metal silicide) is varied.

According to the manufacturing steps of the semiconductor device in this embodiment again, gate electrodes 4, 7 and 8 comprising NiSi and the gate electrode 5 comprising Ni₃Si can be formed by implementing the following method.

First, as can be found from the above steps, the film thickness of the gate electrodes 4, 7 and 8 are about 120 nm and the film thickness of the gate electrode 5 is about 40 nm. Furthermore, the film thickness of the Ni films 23 on the gate electrodes 4, 5, 7, and 8 is about 150 nm. Thus, the film thickness ratio among the gate electrodes 4, 7 and 8 (polysilicon film) and the Ni film 23 is different from that between the gate electrode 5 (polysilicon film) and the Ni film 23.

In this structure, the RTA process is performed at 340° C. for 240 seconds in a first heat treatment. Then, an unreacted Ni film 23 that has not been silicided is removed by using mixed acid solution (having the volume ratio such that phosphoric acid:nitric acid:acetic acid:hydrogen peroxide solution=40:1:2:3:1.3). Then, the RTA process is performed at 500° C. for 90 seconds in a second heat treatment.

That is, the gate electrodes 4, 7 and 8 are partially silicided (the gate electrode 5 is almost fully silicided) in the first heat treatment and then after the Ni film 23 has been selectively removed, all of the gate electrodes 4, 5, 7 and 8 are fully silicided in the second heat treatment.

By implementing the above method, in the gate electrode structure 50, the gate electrode 4 in which NiSi (that is, its composition ratio is such that Ni:Si=1:1) is silicided is formed. In addition, in the gate electrode structure 51, the gate electrode 5 in which Ni₃Si (that is, its composition ratio is such that Ni:Si=3:1) is silicided is formed. In addition, in the gate electrode structure 52, the gate electrode 7 in which NiSi (that is, its composition ratio is such that Ni:Si=1:1) is silicided is formed. In addition, in the gate electrode structure 53, the gate electrode 8 in which NiSi (that is, its composition ratio is such that Ni:Si=1:1) is silicided is formed.

In addition, as described above, the gate electrodes 4 and 5 directly formed on the high-dielectric gate insulation film 3 have different phase structures (composition ratios). Therefore, as discussed above, the transistor having the gate electrode structure 50 has a threshold voltage different from that of the transistor having the gate electrode structure 51.

Here, when the SiN film 18 existing on the gate electrode structure 51 formed in the core part 100 is removed and polysilicon (gate electrode 5) constituting the gate electrode structure 51 is reduced, the process in which the SiN films existing on the gate electrode structures 52 and 53 formed in the I/O part 200 are removed and polysilicon (gate electrodes 7 and 8) constituting the gate electrode structures 52 and 53 are reduced may be performed at the same time.

In this case, the phase structure (composition) of the silicided gate electrodes 7 and 8 is not NiSi but Ni₃Si. However, as discussed above, even when the phase structure (composition) of the gate electrodes 7 and 8 directly formed on the SiON gate insulation film 6 varies, the threshold voltage of the transistor hardly varies.

Through the above series of steps, the semiconductor device shown in FIG. 5 is provided.

As described above, in the region where the gate insulation film is required to be thinned (for example, the EOT (Equivalent Oxide Thickness is required to be thinned), the high-dielectric gate insulation film is used, and in the region where the gate insulation film is not really required to be thinned (for example, the EOT is not really required to be thinned), the SiON (or SiO₂) film is used as the gate insulation film.

In this case, when the phase structure (composition) of the gate electrode directly formed on the high-dielectric gate insulation film (for example, HfSiON film) is varied, the threshold voltage of the transistor having the high-dielectric gate insulation film can be varied. Meanwhile, when the kind (and/or concentration) of the impurity element doped in the gate electrode directly formed on the SiON (or SiO₂) film is varied, the threshold voltage of the transistor having the gate insulation film comprising the SiON film and the like can be varied.

In addition, even when the kind (and/or concentration) of the impurity element having a predetermined conductivity type in the gate electrode directly formed on the high-dielectric gate insulation film (HfSiON film, for example) is varied, the threshold voltage of the transistor having the high-dielectric gate insulation film is not varied.

Furthermore, the SiON gate insulation film 6 is interposed between the high-dielectric gate insulation film 3 and the gate electrodes 7 and 8 in the above constitution. Therefore, even when the phase structure (composition) of the gate electrodes 7 and 8 directly formed on the SiON gate insulation film 6 is varied, the threshold voltage of the transistor having the SiON gate insulation film 6 is not varied.

Here, when the case where the phase structure (composition) of the gate electrode directly formed on the high-dielectric gate insulation film is compared with the case where the kind (and/or concentration) of the impurity element having a predetermined conductivity type doped in the gate electrode directly formed on the SiON (or SiO₂) film is varied, accuracy is high and the control width of the threshold voltage of the transistor is larger in the latter case.

Therefore, in view of miniaturization and adjustment of the threshold voltage, a more desirable structure is such that the high-dielectric gate insulation film 3 is formed and the phase structure (composition) of the gate electrodes 4 and 5 directly formed on the high-dielectric gate insulation film 3 is varied in the core part 100, and the SiON gate insulation film 6 is formed and the kind (and/or concentration) of the impurity element having a predetermined conductivity type doped in the gate electrode 7, 8 directly formed on the SiON gate insulation film 6 is varied in the I/O part 200.

In addition, the operation voltage of the transistor formed in the I/O part 200 is higher than that of the transistor formed in the core part 100 in general.

Therefore, when the gate insulation film formed in the I/O part 200 is provided by stacking the high-dielectric gate insulation film 3 and the SiON gate insulation film 6, resistance to voltage can be more improved in the I/O part 200 as described above.

In addition, the gate electrodes 4, 5, 7 and 8 may not necessarily comprise metal silicide and may comprise alloy and the like.

However, when the gate electrodes 4, 5, 7 and 8 comprise metal silicide, the manufacturing process of the semiconductor device according to this embodiment is consistent with the manufacturing process of the existing semiconductor device (that is, the process for forming a gate electrode comprising polysilicon). More specifically, the semiconductor device according to this embodiment can be manufactured without varying the process of the existing semiconductor device so much.

In addition, when the gate electrodes 4, 5, 7 and 8 comprise metal silicide, the metal silicide having different phase structure can be easily formed. That is, the phase structure (composition ratio) of the metal silicide can be varied only by adjusting the film thickness ratio between polysilicon and metal such as Ni.

### Embodiment 2

According to the embodiment 1, even when the threshold voltage is also varied by varying the phase structure (composition) of the gate electrode, the impurity element having a predetermined conductivity type is doped in the gate electrode. For example, focusing on the core part 100, the threshold voltages of the transistors comprising the gate electrodes 4 and 5 are varied by varying the phase structure (composition) of the gate electrodes 4 and 5. The impurity element such as As or P is doped in the gate electrode 4, and the impurity element such as B is doped in the gate electrode 5.

Meanwhile, a semiconductor device according to this embodiment is characterized in that an impurity element having a predetermined conductivity type is not doped in gate electrodes (regarded as a first gate electrode and a second gate electrode) in the case where the threshold voltage is varied by varying the phase structure (composition) of the gate electrode. That is, it is characterized in that the gate electrode is non-doped when the threshold voltage is varied by varying the phase structure (composition) of the gate electrode.

According to the semiconductor device regarding this embodiment, gate electrodes 4 and 5 are non-doped in FIG. 5. Since the structure other than that is the same as that of the semiconductor device regarding the embodiment 1, the description thereof will be omitted.

A manufacturing method of the semiconductor device according to this embodiment will be described in detail with reference to process sectional views. Here, steps from FIG. 6 to FIG. 10 are the same as those described in the embodiment 1.

Then, as shown in FIG. 21, in an I/O part 200, a resist 26 having an opening positioned at a region in which a gate electrode structure 52 that will be described below is to be formed is formed on a SiN film 18. Then, using the resist 26 as a mask, an impurity element such as P or As is doped in a polysilicon film 17. As a result, as shown in FIG. 21, a first impurity doped region 27 is formed in the polysilicon film 17.

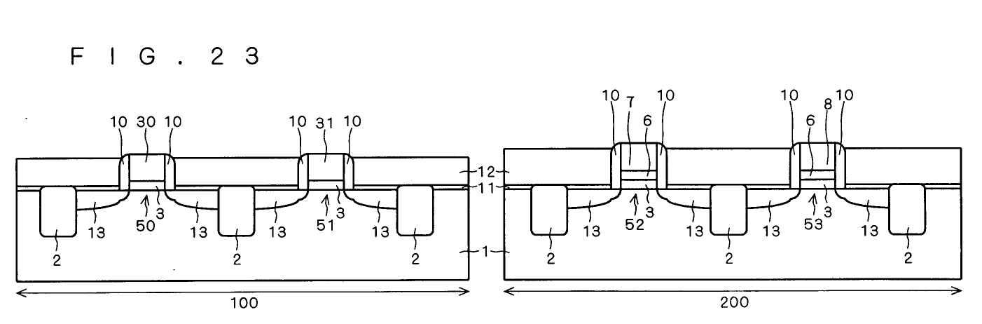

Then, the resist film 26 is removed. Then, as shown in FIG. 22, in the I/O part 200, a resist 28 having an opening positioned at a region in which a gate electrode structure 53 that will be described below is to be formed is formed on the SiN film 18. Thus, using the resist 28 as a mask, B is doped in a desired concentration in the polysilicon film 17. As a result, as shown in FIG. 22, a second impurity doped region 29 is formed in the polysilicon film 17.

As can be seen from the steps described with reference to FIGS. 21 and 22, the impurity element having a predetermined conductivity type is not doped in the core part 100 but doped only in the I/O part 200. That is, the impurity element having a predetermined conductivity type is not doped in the polysilicon film 17 in the region where the threshold voltage is varied by varying the phase structure (composition) of the gate electrode.

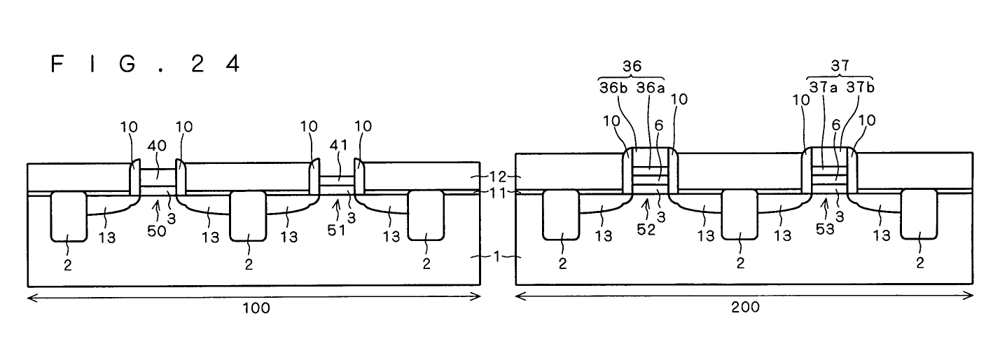

After the resist film 28 has been removed, the steps after FIG. 11 described in the embodiment 1 are implemented. Thus, the semiconductor device having the structure shown in FIG. 23 is provided.

As can be seen from the comparison between FIGS. 5 and 23, the outer configurations of the semiconductor device according to the embodiment 1 and of the semiconductor device according to the embodiment 2 are almost the same.

However, as can be seen from the above steps, according to the semiconductor device according to this embodiment (FIG. 23), the impurity element is not doped in a gate electrode 30 constituting a gate electrode structure 50, and the impurity element having a predetermined conductivity type is not doped in a gate electrode 31 constituting a gate electrode structure 51. That is, the gate electrodes 30 and 31 are non-doped.

In addition, the impurity element having a predetermined conductivity type is doped in a gate electrode 7 constituting a gate electrode structure 52 and a gate electrode 8 constituting a gate electrode structure 53 similar to the embodiment 1. The constitution other than the gate electrodes 30 and 31 is the same as that of the semiconductor device according to the embodiment 1.

As described above, according to the semiconductor device regarding this embodiment, the threshold voltage of the transistor is varied by varying the phase structure (composition) of the gate electrodes 30 and 31. The impurity element having a predetermined conductivity type is not doped in the gate electrodes 30 and 31 (regarded as the first gate electrode and the second gate electrode). That is, the gate electrodes 30 and 31 are non-doped.

Therefore, in the region (the core region 200 in this embodiment) where the threshold voltage is controlled by varying the phase structure (composition) of the gate electrodes 30 and 31, the gate electrodes 30 and 31 can be easily fully silicided (that is, the siliciding operation can be easily controlled).

This is because polysilicon doped with the impurity element having a predetermined conductivity type is likely to be prevented from being silicided as compared with non-doped polysilicon in general (that is, the siliciding operation is hard to control).

### Embodiment 3

According to the semiconductor device regarding the embodiment 1, all of the gate electrodes 4, 5, 7 and 8 are fully silicided.

Meanwhile, a semiconductor device according to this embodiment, gate electrodes (gate electrodes formed on a SiON film or SiO₂ film and regarded as a third gate electrode and a fourth gate electrode) in which an impurity element is doped to vary the threshold voltage of the transistor are not fully silicided.

That is, according to the semiconductor device in this embodiment, the gate electrode directly formed on the SiON film or SiO₂ film has a stacked structure in which polysilicon film and a metal silicide film are stacked in this order. Here, an impurity element having a different kind and/or concentration is doped in the gate electrode (both of polysilicon film and metal silicide film), whereby the threshold voltage of a transistor having the gate electrode is varied.

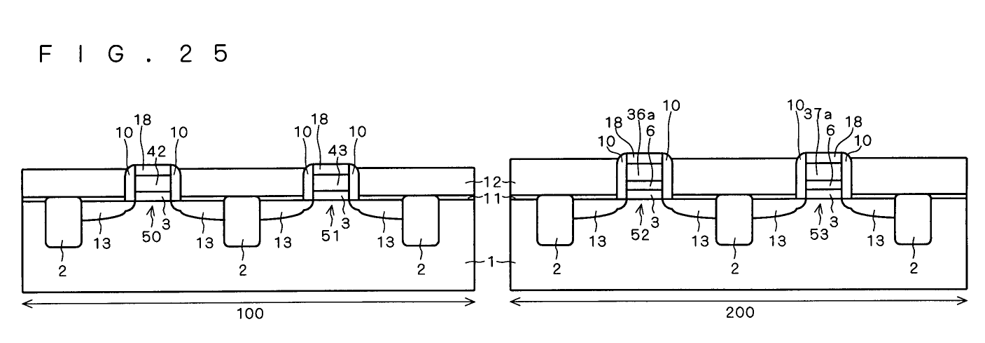

FIG. 24 is a sectional view showing the essential constitution of the semiconductor device according to this embodiment.

Focusing on gate electrode structures 52 and 53 formed in an I/O part 200, the gate electrode structures 52 and 53 have the following constitutions.

In a predetermined position in a semiconductor substrate 1, a gate insulation film in which a high-dielectric gate insulation film 3 comprising a HfSiON film and a SiON gate insulation film 6 are stacked in this order is formed. On the SiON gate insulation films 6, gate electrodes 36 and 37 in which polysilicon films 36a and 37a and Ni silicide films 36b and 37b are stacked in this order are formed, respectively.

Here, in the gate electrode structure 52, As or P is doped in the polysilicon film 36a. In addition, the Ni silicide film 36b has the phase structure (composition) of NiSi, in which As or P is doped also. In addition, in the gate electrode structure 53, B is doped in the polysilicon film 37a. In addition, the Ni silicide film 37b has the phase structure (composition) of NiSi, in which B is doped also.

Meanwhile, focusing on gate electrode structures 50 and 51 in the core part 100, their constitutions are almost the same as those described in the embodiment 1. However, the film thickness of the gate electrode and the like are different from those described in the embodiment 1. That is, according to this embodiment, the gate electrode structures 50 and 51 have the following constitutions.

In a predetermined position of the semiconductor substrate 1, a high-dielectric gate insulation film 3 comprising the HfSiON film is formed. On the high-dielectric gate insulation film 3, gate electrodes 40 and 41 comprising Ni silicide are formed.

Here, in the gate electrode structure 50, the gate electrode 40 is non-doped and has the phase structure (composition) of NiSi. In addition, in the gate electrode structure 51, the gate electrode 41 is non-doped and has the phase structure (composition) of Ni₃Si. In addition, the film thickness of the gate electrode 41 is thinner than that of the gate electrode 40.

A manufacturing method of the semiconductor device according to this embodiment will be described in detail with reference to step sectional views hereinafter. Here, steps from FIG. 6 to FIG. 15 are the same as those described in the embodiments. In addition, according to this embodiment, the gate electrodes 40 and 41 are non-doped in core part 100. Therefore, the steps described in the embodiment 2 (FIGS. 21 and 22) are used in the steps from FIGS. 6 to 15.

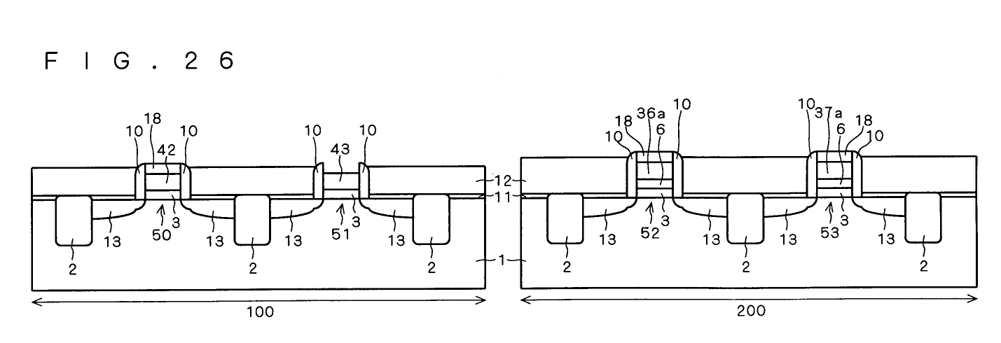

Thus, according to this embodiment, the structure shown in FIG. 25 is formed by implementing the steps shown in FIGS. 6 to 15 employing the steps according to the embodiment 2 partially.

Here, according to the structure shown in FIG. 25, a polysilicon film 42 of the gate electrode structure 50 and a polysilicon film 43 of the gate electrode structure 51 are non-doped. In addition, As or P is doped in the polysilicon film 36a of the gate electrode structure 52. Furthermore, B is doped in the polysilicon film 37a of the gate electrode structure 53. In addition, the constitution other than the above is the same in FIGS. 25 and 15.

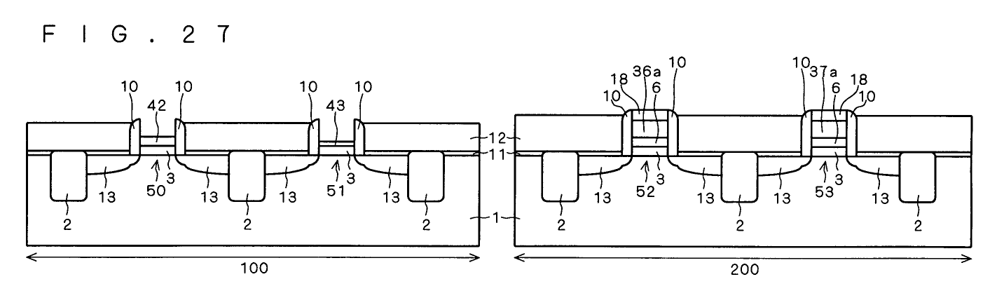

Then, in the gate electrode structure 51 formed in the core part 100, a SiN film 18 formed on the polysilicon film 43 is processed by photochemical engraving and etching. Thus, only the SiN film 18 formed on the polysilicon film 43 is removed. Then, the polysilicon film 43 is processed by etching. Thus, the film thickness of the polysilicon 43 is removed by ⅓ as shown in FIG. 26.

Here, the initial film thickness of the polysilicon films 42, 43, 36a and 37a are about 120 nm. Therefore, by the etching to the polysilicon film 43, the film thickness of the polysilicon 43 becomes about 80 nm.

Then, in the gate electrode structure 50 formed in the core part 100, a SiN film 18 formed on the polysilicon film 42 is processed by photochemical engraving and etching, whereby only the SiN film 18 formed on the polysilicon film 42 is removed.

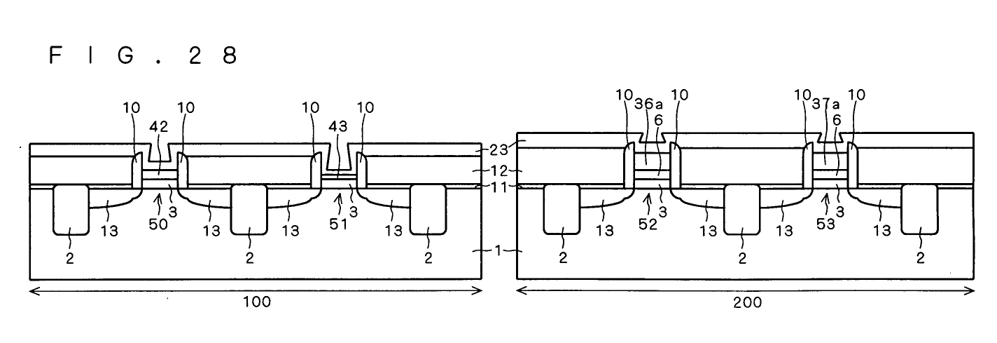

Then, the polysilicon film 42 and the polysilicon film 43 are processed by etching. Thus, as shown in FIG. 27, the film thicknesses of the polysilicon films 42 and 43 are reduced. Here, through the etching process, the film thickness of the polysilicon 42 is reduced by about ½ and the polysilicon 43 is also removed by the same amount of the above. Therefore, the film thickness of the polysilicon 43 becomes about ⅙ of the initial film thickness.

That is, by the etching process to the polysilicon films 42 and 43, the polysilicon film 42 is about 60 nm in thickness, and the polysilicon film 43 is about 20 nm in thickness.

Then, in the gate electrode structures 52 and 53 formed in the I/O part 200, the SiN films 18 formed on the polysilicon films 36a and 37a are processed by photochemical graving and etching. Thus, the SiN films 18 formed on the polysilicon films 36a and 37a are removed.

Thus, the film thickness ratio of the polysilicon films 42, 43, 36a and 37a is as follows. That is, the polysilicon film 42:the polysilicon film 43:the polysilicon film 36a:the polysilicon film 37a=60 nm:20 nm:120 nm:120 nm=3:1:6:6.

Then, a Ni film 23 is formed (refer to FIG. 28) on an interlayer insulation film 12 so as to fill the upper part of the gate electrode structures 50 to 53. Here, the film thickness of the Ni film 23 is about 75 nm.

Then, the polysilicon films 42, 43, 36a and 37a are silicided. Here, as described in the embodiment 1, the phase structure (composition) of the Ni silicide (metal silicide) can be varied by varying the film thickness ratio between polysilicon and Ni (metal for siliciding).

According to the manufacturing steps of the semiconductor device in this embodiment again, the gate electrode 40 comprising NiSi, the gate electrodes 36 and 37 having the Ni silicide films 36b and 37b (the Ni silicide films 36b and 37b are composed of SiNi) partially, and the gate electrode 41 comprising Ni₃Si can be formed by implementing the following method.

First, as can be seen from the above steps, the film thicknesses of the polysilicon films 42, 43, 36a and 37a are such that the polysilicon film 42 the polysilicon film 43:the polysilicon film 36a:the polysilicon film 37a=60 nm:20 nm:120 nm:120 nm. In addition, the film thickness of the Ni film 23 on the polysilicon films 42, 43, 36a and 37a is about 75 nm. Thus, the film thickness ratio among the polysilicon films 42, 43, 36a and 37a and the Ni film 23 is different from each other (the film thickness ratio between the polysilicon film 36a and Ni film 23 and the film thickness ratio between the polysilicon film 37a and Ni film 23 are the same).

In this structure, the RTA process is performed at 340° C. for 60 seconds in a first heat treatment. Then, an unreacted Ni film 23 that has not been silicided is removed by using mixed acid solution (having the volume ratio such that phosphoric acid:nitric acid:acetic acid:hydrogen peroxide solution=40:1:2:3:1.3). Then, the RTA process is performed at 500° C. for 90 seconds in a second heat treatment.

That is, the polysilicon films 42, 36a and 37a are partially silicided (the polysilicon film 43 is almost fully silicided) in the first heat treatment and then after the Ni film 23 has been selectively removed, the polysilicon film 42 is fully silicided in the second heat treatment (the polysilicon films 36a and 37a are not fully silicided and polysilicon is left on the side of the gate insulation film (the side of the SiON gate insulation film 6)).

By implementing the above method, in the gate electrode structure 50, the gate electrode 40 in which NiSi (that is, its composition ratio is such that Ni:Si=1:1) is fully silicided is formed. In addition, in the gate electrode structure 51, the gate electrode 41 in which Ni₃Si (that is, its composition ratio is such that Ni:Si=3:1) is fully silicided is formed (refer to FIG. 24).

In addition, in the gate electrode structure 52, the gate electrode 36 comprising the Ni silicide film 36b (that is, a NiSi film and its composition ratio is such that Ni:Si=1:1) and polysilicon 36a is formed. In addition, in the gate electrode structure 53, the gate electrode 37 comprising Ni silicide film 37b (that is, a NiSi film its composition ratio is such that Ni:Si=1:1) and polysilicon 37a is formed (refer to FIG. 24).

Through the above series of steps, the semiconductor device shown in FIG. 24 is provided.

As described above, according to the semiconductor device regarding this embodiment, the gate electrodes 36 and 37 directly formed on the SiON gate insulation film 6 (the same applies to the gate insulation film comprising the SiO₂ film as discussed above) have stacked structure in which the polysilicon films 36a and 37a and the metal silicide films 36b and 37b are stacked in this order, respectively.

That is, the gate electrode formed in the region (I/O part 200) in which the threshold voltage of the transistor is adjusted (controlled) by doping the impurity element having a predetermined conductivity type has the stacked structure (metal silicide/polysilicon) on the SiON film or the SiO₂ film.

Thus, when the constitution in which the polysilicon films 36a and 37a comprising the impurity element having a predetermined conductivity type are directly formed on the SiON film or the SiO₂ film is compared with the constitution in which the metal silicide film comprising the impurity element having a predetermined conductivity type is directly formed on the SiON film or the SiO₂ film (when the gate electrodes 7 and 8 are fully silicided like in the embodiments 1 and 2), the effective work function of the former constitution (when both constitutions are the same, the threshold voltage) can be more easily adjusted (controlled). Furthermore, the effective work function can be adjusted (controlled) in a wider range.

In addition, according to the embodiment 3, the gate electrodes 40 and 41 formed in the core 100 are non-doped. However, an impurity element having a predetermined conductivity type may be doped in the gate electrodes 40 and 41. In this case, it is to be noted that as described in the embodiment 1, in the core part 100, the impurity elements doped in the gate electrodes 40 and 41 do not affect the variation of the threshold voltage of the transistor. Here, in this case also, it is necessary to adjust the heights of the polysilicon films 42 and 43 before the polysilicon films 42 and 43 are fully silicided in the core part 100.

In addition, the HfSiON film is used for the high-dielectric gate insulation film 3 in the above embodiments. However, even when another gate insulation film is used as high-dielectric gate insulation film, the same effect as the above (the effect that the threshold voltage can be varied by varying the phase structure (composition) of the gate electrode directly formed on the high-dielectric gate insulation film) can be provided as long as the gate insulation film has a dielectric constant higher than that of SiON.

In addition, according to the above embodiments, the metal silicide is employed as the gate electrode, and the transistors having different threshold voltages are formed in one semiconductor device by varying the phase structure (composition) of the metal silicide in the core part 100 (the first region).

However, the metal silicide is not necessarily employed as the gate electrode, and the gate electrode may comprise another material (metal, an alloy, a compound containing metal silicide) comprising a predetermined metal element and another element. In this case, the threshold voltage of the transistor can be varied by varying a composition ratio between the predetermined metal element and the other element.

For example, a metal silicide film that can provide the same effect as that of the present invention includes a platinum silicide film, a tantalum silicide film, a hafnium silicide film and the like other than the Ni silicide. In addition, an alloy film that can provide the same effect as that of the present invention includes an alloy in which metal element for NMOS such as Ta, Hf or Al is combined with metal element for PMOS such as Ru, W, Ir, or Re. Furthermore, a compound film that can provide the same effect as that of the present invention includes a nitride compound such as TiN, WN, TaN, or HfN, a silicon nitride compound such as TiSiN, TaSiN, or HfSiN, and a carbide compound such as TaC.

In any case, the gate electrode directly formed on the high-dielectric gate insulation film 3 in the core part 100 comprises a predetermined metal element and another element(may be metal or may not be metal). In addition, the threshold voltage of the transistor can be varied in the core part 100 by varying the composition ratio between the predetermined metal and the other element.

Furthermore, the high-dielectric gate insulation film 3 may be a singular high-dielectric film layer. In addition, in view of the dielectric constant of the gate insulation film, transistor characteristics, gate leak characteristics and the like, it may comprise a plurality of layers comprising a high-dielectric film and another insulation film.

However, in the case of the plurality of layers, since it is necessary to vary the threshold voltage by varying the phase structure (composition) of the gate electrode in the core part 100, the part that is in contact with the gate electrode has to be the high-dielectric film.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising a first region and a second region, wherein
in said first region, said semiconductor device comprises
a first gate electrode comprising a first material composed of a predetermined metal element and another element at a first ratio,
a second gate electrode comprising a second material composed of said predetermined metal element and said another element at a second ratio, and
a high-dielectric gate insulation film formed between said first gate electrode and a semiconductor substrate, and between said second gate electrode and said semiconductor substrate, and being in contact with said first gate electrode or said second gate electrode, and having a dielectric constant higher than that of SiON,
in said second region, said semiconductor device comprises
a third gate electrode containing a first impurity element in a first concentration,
a fourth gate electrode containing a second impurity element in said first concentration, or containing said first impurity element in a second concentration, or containing said second impurity element in said second concentration, and
a gate insulation film formed between said third gate electrode and said semiconductor substrate and between said fourth gate electrode and said semiconductor substrate, and being in contact with said third gate electrode or said fourth gate electrode, and comprising SiON film or SiO₂ film.

2. The semiconductor device according to claim 1, wherein
said first region is a core part, and
said second region is an I/O part.

3. The semiconductor device according to claim 2, wherein
in said I/O part,
said high-dielectric gate insulation film is formed between said gate insulation film and said semiconductor substrate.

4. The semiconductor device according to claim 1, wherein
said first, second, third and fourth gate electrodes comprise metal silicide.

5. The semiconductor device according to claim 4, wherein
an impurity element having a predetermined conductivity type is not contained in said first gate electrode and said second gate electrode.

6. The semiconductor device according to claim 1, wherein
said high-dielectric gate insulation film comprises HfSiON.

7. The semiconductor device according to claim 3, wherein
said high-dielectric gate insulation film comprises HfSiON.

8. The semiconductor device according to claim 1, wherein
each of said third gate electrode and said fourth gate electrode has the structure in which polysilicon film and metal silicide film are stacked in this order.
